(19) United States
(12) Patent Application Publication
(10) Pub. No.: US 2018/0204818 A1
(43) Pub. Date: Jul. 19, 2018

(54) MANUFACTURING METHOD FOR PACKAGE DEVICE

(71) Applicant: DISCO CORPORATION, Tokyo (JP)

(72) Inventor: Kazuma Sekiya, Tokyo (JP)

(21) Appl. No.: 15/874,586

(22) Filed: Jan. 18, 2018

(30) Foreign Application Priority Data
Jan. 18, 2017 (JP) 2017-006965

(51) Int. Cl. H01L 23/00; H01L 23/13; H01L 21/78

(52) U.S. Cl. CPC H01L 24/83; H01L 2224/27848; H01L 24/92; H01L 24/32; H01L 24/48; H01L 24/49; H01L 23/13; H01L 21/78; H01L 24/27; H01L 2224/83385; H01L 2224/83191; H01L 2224/83948; H01L 2224/73265; H01L 2224/92247; H01L 2224/32238; H01L 2224/32237; H01L 2224/48227; H01L 2224/49176; H01L 2924/1511; H01L 2924/15153; H01L 2224/27312; H01L 2224/27901; H01L 24/73

(57) ABSTRACT

A manufacturing method for a package device includes a chip preparation step of preparing a device chip that includes an adhesive layer, a mounting substrate preparation step of preparing a mounting substrate that has a chip adhesion region to which the device chip is to be adhered, an electrode portion to be connected to the device chip, and a stepped portion formed between the chip adhesion region and the electrode portion, a mounting step of adhering the device chip to the chip adhesion region of the mounting substrate, a hardening step of hardening the adhesive layer, a connection step of electrically connecting the device chip and the electrode portion by a wire, and a molding step of covering the device chip and the wire with mold resin.

### BACKGROUND OF THE INVENTION

### Field of the Invention

The present invention relates to a manufacturing method for a package device.

### Description of the Related Art

A semiconductor device chip used in various electronic apparatus is adhered to and used together with a frame for die bonding or a mounting substrate. Conventionally, a semiconductor device chip is adhered using silver paste applied to a frame or a substrate as an adhesive. However, since it is difficult to apply silver paste by an appropriate amount to a narrow region, an adhesive film called die attach film (DAF) has become used widely. The DAF is pasted to a rear face of a semiconductor wafer and is divided when the semiconductor wafer is divided into chips such that it is provided as an adhesive layer of a size equal to that of the chip on the rear face of the chip.

However, in such a case that a wafer is divided by laser processing or is divided by so-called dicing before grinding (DBG) process, it is necessary to separately perform dividing processing of the DAF (cool expand or laser ablation processing), which is not reasonable (refer, for example, to Patent Documents 1 and 2). Further, as the chip size decreases, the number of processing steps increases. Therefore, there is a subject that increased time is required for division of the DAF and the time required for manufacturing the device increases.

Therefore, it has been proposed to splay adhesive in the form not of a film but of liquid to a chip to form an adhesive layer having an area corresponding to that of the chip (refer, for example, to Japanese Patent No. 5479866). An adhesive layer configured by applying adhesive in the form of liquid is temporarily hardened and then adhered to a mounting substrate.

### SUMMARY OF THE INVENTION

However, the adhesive layer configured by applying adhesive in the form of liquid as disclosed in Japanese Patent No. 5479866 has comparatively high flexibility in comparison with a DAF in the form of a film, and therefore is likely to spread around by pressure upon adhesion, and there is the possibility that the adhesive layer may cover also an electrode pad of a mounting substrate.

Therefore, it is an object of the present invention to provide a manufacturing method for a package device by which it is possible to suppress an electrode portion from being covered with an adhesive layer while it is suppressed that time required for manufacturing a package device becomes long.

In accordance with an aspect of the present invention, there is provided a manufacturing method for a package device, including a chip preparation step of preparing a device chip that includes an adhesive layer applied in the form of liquid and temporarily hardened on one face thereof, a mounting substrate preparation step of preparing a mounting substrate that has, on a front face thereof, a chip adhesion region to which the device chip is to be adhered, an electrode portion that is provided in the proximity of the chip adhesion region and is to be electrically connected to the adhered device chip, and a stepped portion formed between the chip adhesion region and the electrode portion, a mounting step of adhering the device chip to the chip adhesion region of the mounting substrate through the adhesive layer, a hardening step of giving, after the mounting step is carried out, an external stimulus to the adhesive layer to harden the adhesive layer, a connection step of electrically connecting, after the hardening step is carried out, the device chip and the electrode portion by a wire, and a molding step of covering, after the connection step is carried out, the device chip and the wire with mold resin, the stepped portion suppressing the adhesive layer in the temporarily hardened state from protruding to the electrode portion.

Preferably, a difference in height is formed between the chip adhesion region and the electrode portion by the stepped portion.

Preferably, the stepped portion is a groove formed between the chip adhesion region and the electrode portion.

The manufacturing method for a package device of the present invention exhibits an effect that it is possible to suppress the electrode portion from being covered with the adhesive layer while it is suppressed that time required for manufacturing a package device becomes long.

The above and other objects, features and advantages of the present invention and the manner of realizing them will become more apparent, and the invention itself will best be understood from a study of the following description and appended claims with reference to the attached drawings showing some preferred embodiments of the invention.

### BRIEF DESCRIPTION OF THE DRAWINGS

FIG. 1 is a perspective view depicting part of a package device manufactured by a manufacturing method for a package device according to a first embodiment;

FIG. 2 is a flow chart depicting a flow of the manufacturing method for a device chip of a package device according to the first embodiment;

FIG. 3A is a perspective view depicting a separation groove formation step of the manufacturing method for a device chip of a package device depicted in FIG. 2;

FIG. 3B is a sectional view taken along line IIIb-IIIb in FIG. 3A;

FIG. 4A is a perspective view depicting a protective member sticking step of the manufacturing method for a device chip of a package device depicted in FIG. 2;

FIG. 4B is a perspective view after the protective member sticking step of the manufacturing method for a device chip of a package device depicted in FIG. 2;

FIG. 5A is a perspective view depicting a division step of the manufacturing method for a device chip of a package device depicted in FIG. 2;

FIG. 5B is a perspective view after the division step of the manufacturing method for a device chip of a package device depicted in FIG. 2;

FIG. 6A is a perspective view depicting a die bonding resin laying step of the manufacturing method for a device chip of a package device depicted in FIG. 2;

FIG. 6B is a perspective view depicting a state in which adhesive at the die bonding resin laying step depicted in FIG. 6A is temporarily hardened;

FIG. 7 is a perspective view depicting a transferring step of the manufacturing method for a device chip of a package device depicted in FIG. 2;

FIG. 8A is a sectional view depicting a separation step of the manufacturing method for a device chip of a package device depicted in FIG. 2;

FIG. 8B is a perspective view depicting a device chip manufactured by the manufacturing method for a device chip of a package device depicted in FIG. 2;

FIG. 9 is a flow chart depicting another flow of the manufacturing method for a package device according to the first embodiment;

FIG. 10 is a perspective view depicting a mounting step of the manufacturing method for a package device depicted in FIG. 9;

FIG. 11 is a sectional view depicting the mounting step of the manufacturing method for a package device depicted in FIG. 9;

FIG. 12 is a sectional view depicting a hardening step of the manufacturing method for a package device depicted in FIG. 9;

FIG. 13 is a sectional view depicting a connection step of the manufacturing method for a package device depicted in FIG. 9;

FIG. 14 is a sectional view depicting a molding step of the manufacturing method for a package device depicted in FIG. 9;

FIG. 15 is a perspective view depicting a mounting step of a manufacturing method for a package device according to a second embodiment;

FIG. 16 is a sectional view depicting the mounting step of the manufacturing method for a package device according to the second embodiment;

FIG. 17 is a sectional view depicting a hardening step of the manufacturing method for a package device according to the second embodiment;

FIG. 18 is a sectional view depicting a connection step of the manufacturing method for a package device according to the second embodiment;

FIG. 19 is a sectional view depicting a molding step of the manufacturing method for a package device according to the second embodiment; and

FIG. 20 is a sectional view depicting a package device manufactured by a manufacturing method for a package device according to a third embodiment.

### DETAILED DESCRIPTION OF THE PREFERRED EMBODIMENTS

Modes (embodiments) for carrying out the present invention are described in detail with reference to the drawings. The present invention shall not be restricted by the substance described in the following description of the embodiments. Further, components described hereinbelow include those that can be conceived easily by those skilled in the art or those that are substantially same. Further, it is possible to suitably combine the components hereinafter described. Further, omission, replacement or alteration of the components can be made without departing from the spirit and scope of the present invention.

### First Embodiment

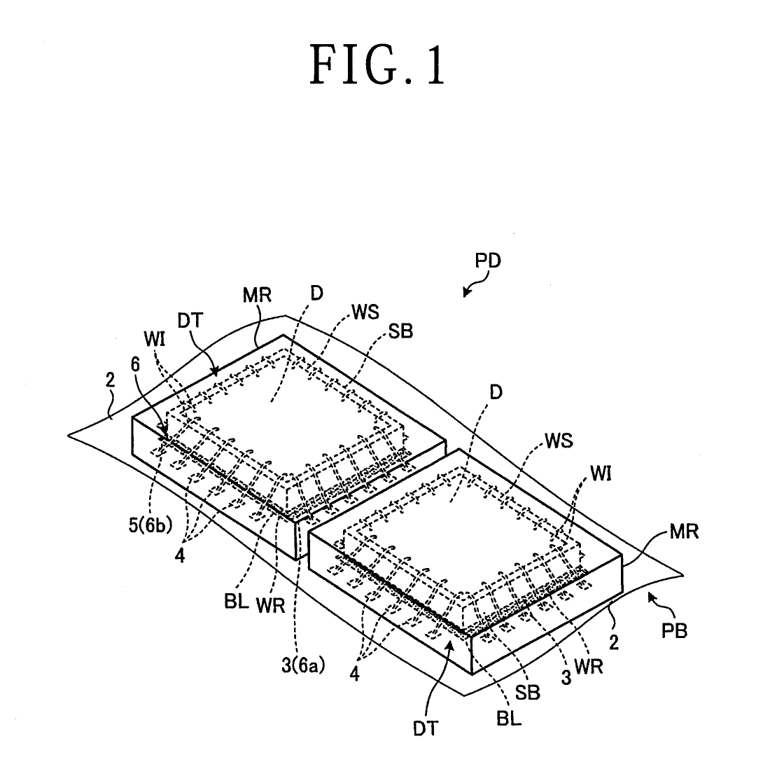

A manufacturing method for a package device according to a first embodiment is described with reference to the drawings. FIG. 1 is a perspective view depicting part of a package device manufactured by the manufacturing method for a package device according to the first embodiment.

The manufacturing method for a package device according to the first embodiment is a method for manufacturing a package device PD depicted in FIG. 1. The package device PD includes a device chip DT, a mounting substrate PB on which the device chip DT is mounted, and mold resin MR as depicted in FIG. 1.

The device chip DT includes a substrate SB, a device D provided on a front face WS of the substrate SB, and an adhesive layer BL provided on a rear face WR that is one face of the substrate SB. The device D is an electronic part such as an integrated circuit (IC), a large-scale integration (LSI) or the like. Although, in the first embodiment, the device D of the device chip DT is a control device for controlling an IC or the like, it is not limited to the control device. One or more such device chips DT are mounted on the mounting substrate PB. The front face of the device D has electrodes not depicted for electric connection to the mounting substrate PB.

The adhesive layer BL is provided to fix the device chip DT to the mounting substrate PB. The adhesive layer BL is configured by temporary hardening of adhesive in the form of liquid after it is applied in a liquid state to the rear face WR. The temporary hardening signifies a state in which at least a surface layer is hardened while the interior side with respect to the surface layer is in the form of liquid. The adhesive layer BL is configured from liquid adhesive that is hardened when an external stimulus is applied thereto. The external stimulus is irradiation of ultraviolet rays or heat. In the first embodiment, the adhesive configuring the adhesive layer BL is temporarily hardened by irradiation of ultraviolet rays thereupon and is generally hardened by heat applied thereto. For the adhesive that configures the adhesive layer BL, a product named “HP20VL” or “ST20VL” by Honghow Specialty Chemicals Inc. or a product named “Ablebond 8200c” by Ablestik Laboratories, or the like can be used.

The mounting substrate PB includes a substrate 2 having an insulation property. Further, the mounting substrate PB has, on the front face of the substrate 2, a chip adhesion region 3 in which the rear face WR of the device chip DT is adhered through the adhesive layer BL, an electrode portion 4 connected to the device chip DT adhered to the chip adhesion region 3, a stepped portion 5 formed between the chip adhesion region 3 and the electrode portion 4, and a wiring pattern not depicted for connecting such electrode portions 4 to each other in a predetermined pattern.

In the first embodiment, the planar shape of the chip adhesion region 3 is a little greater than the planar shape of the rear face WR of the device chip DT. In the first embodiment, the chip adhesion region 3 is formed from a recessed portion 6 that is recessed from the front face of the substrate 2, and the recessed portion 6 has a bottom face 6a. The recessed portion 6 that forms the chip adhesion region 3 is configured on the front face of the substrate 2 by cutting, abrasive processing by irradiation of a laser beam or the like.

The electrode portion 4 is provided in the proximity of the chip adhesion region 3, and a plurality of such electrode portions 4 are provided so as to surround the outer side of the chip adhesion region 3. The electrode portions 4 and the wiring patterns are configured from a metal having conductivity such as copper, copper alloy or the like.

The stepped portion 5 has at least a face 6b crossing with the front face of the substrate 2 and suppresses the adhesive, which configures the adhesive layer BL, from leaking to the outer side of the chip adhesion region 3 to cover the electrode portions 4 and so forth utilizing the surface tension of the adhesive that configures the adhesive layer BL. In the first embodiment, the face 6b of the stepped portion 5 is an inner side face of the recessed portion 6 that forms the chip adhesion region 3 and extends orthogonally with respect to the bottom face 6a that is the chip adhesion region 3. Further, in the first embodiment, since the chip adhesion region 3 is the bottom face 6a of the recessed portion 6, a difference in height in the thicknesswise direction of the substrate 2 is formed between the chip adhesion region 3 and the electrode portions 4 by the face 6b of the stepped portion 5.

Meanwhile, in the package device PD, the electrodes of the device chip DT and the electrode portions 4 of the mounting substrate PB are connected to each other by conductive wires WI. In other words, the device chip DT is mounted on the mounting substrate PB by so-called wire bonding. The mold resin MR is configured from a resin having an insulating property and covers the device chip DT and wires WI.

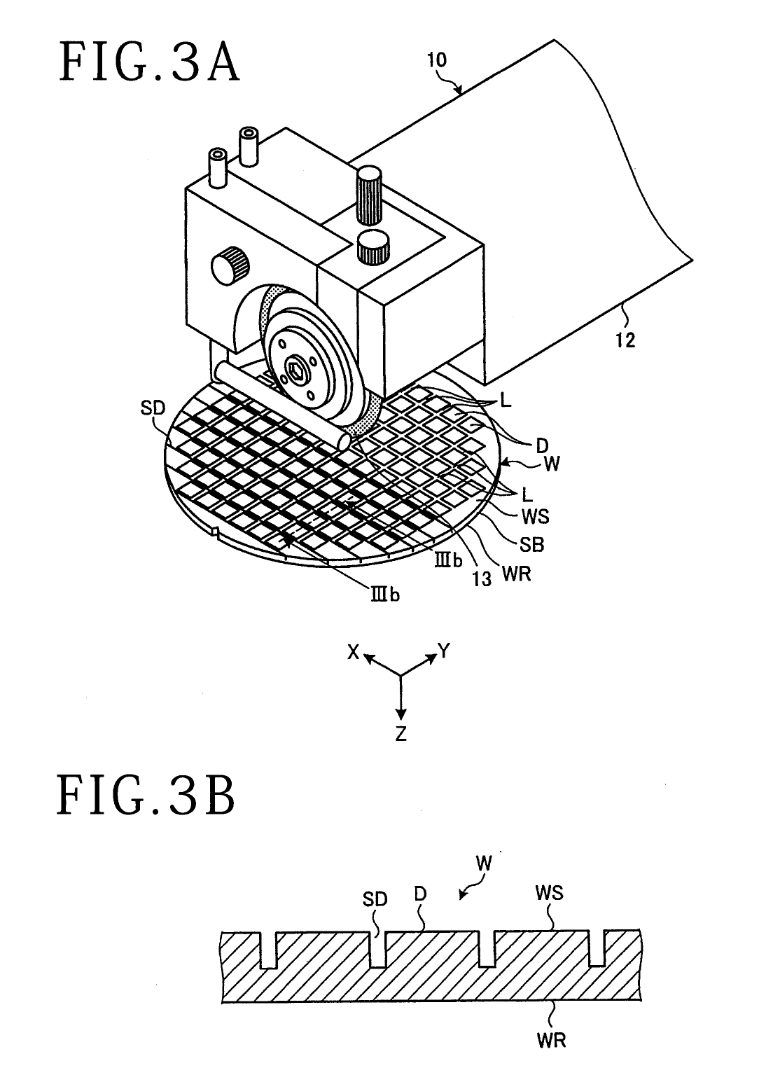

Now, the manufacturing method for the device chip DT of the package device PD is described with reference to the drawings. The manufacturing method for the device chip DT of the package device PD (hereinafter referred to as manufacturing method for the device chip DT) is a method of cutting a wafer W depicted in FIG. 3A along scheduled division lines L to divide the wafer W into individual device chips DT.

The wafer W depicted in FIG. 3A is, in the first embodiment, a semiconductor wafer or an optical device wafer in the form of a disk in which the substrate SB is formed from silicon, sapphire, gallium arsenide or the like. The wafer W has devices D formed in a plurality of regions of the front face WS partitioned by the scheduled division lines L as depicted in FIG. 3A.

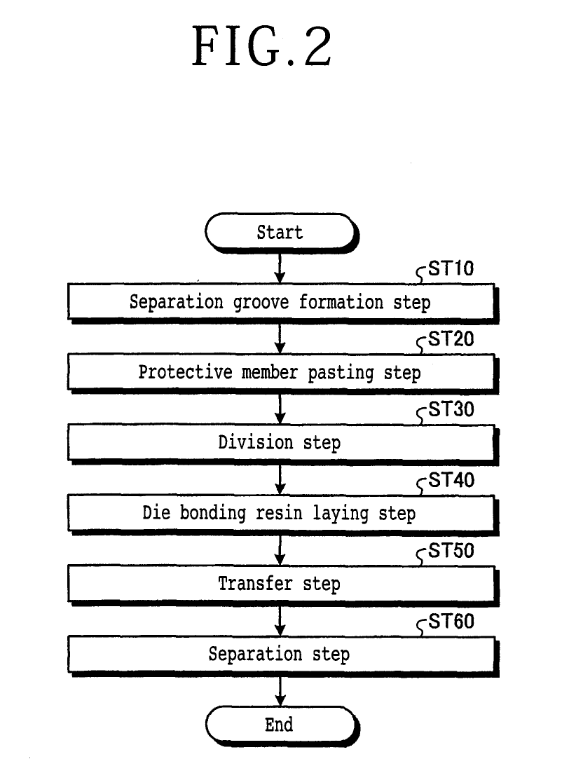

The manufacturing method for the device chip DT includes, as depicted in FIG. 2, a separation groove formation step ST10, a protective member pasting step ST20, a division step ST30, a die bonding resin laying step ST40, a transfer step ST50 and a separation step ST60.

The separation groove formation step ST10 is a step of forming a groove SD along each of the scheduled division lines L on the front face WS of the wafer W. At the separation groove formation step ST10, a groove SD extending along a longitudinal direction of each scheduled division line L is formed on the scheduled division line L. The depth of the groove SD formed at the separation groove formation step ST10 is equal to or greater than a finish thickness (for example, 50 μm) of the substrate SB of the device chip DT, and the width of the groove SD is a predetermined width (for example, 30 μm). In the first embodiment, at the separation groove formation step ST10, while the rear face WR of the wafer W is sucked to and held by a holding face of a chuck table not depicted of a cutting apparatus 10 depicted in FIG. 3A, the grooves SD are formed on the front face WS of the wafer W using a cutting blade 13 of a cutting unit 12.

At the separation groove formation step ST10, the chuck table is moved in an X-axis direction parallel to a horizontal direction by X-axis moving means not depicted and the cutting blade 13 of the cutting unit 12 is moved in a Y-axis direction parallel to the horizontal direction and orthogonal to the X-axis direction by Y-axis moving means not depicted, and the cutting blade 13 of the cutting unit 12 is moved in a Z-axis direction parallel to a vertical direction by Z-axis moving means not depicted to cause the cutting blade 13 to cut in along the scheduled division line L thereby to form a groove SD on the front face WS along each scheduled division line L of the wafer W as depicted in FIG. 3B.

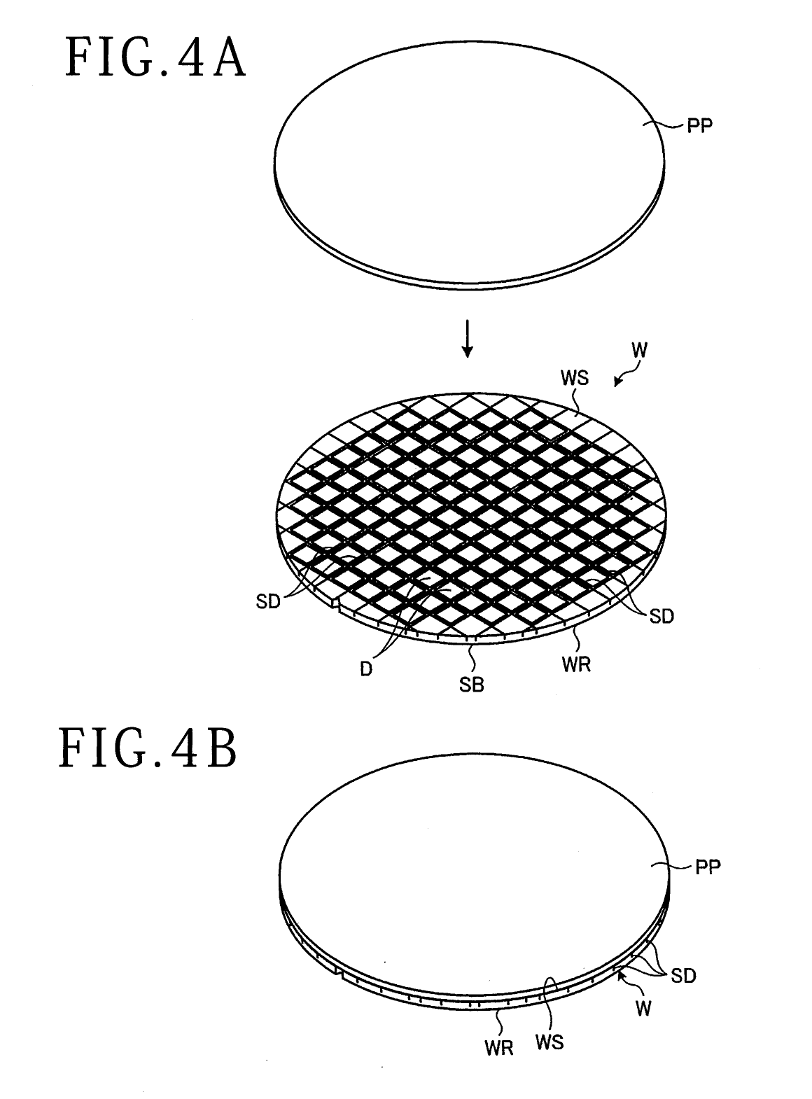

The protective member pasting step ST20 is a step of pasting a protective member PP to the front face WS of the wafer W. In the first embodiment, at the protective member pasting step ST20, the front face WS of the wafer W and the protective member PP are opposed to each other as depicted in FIG. 4A, whereafter the protective member PP is pasted to the front face WS of the wafer W as depicted in FIG. 4B.

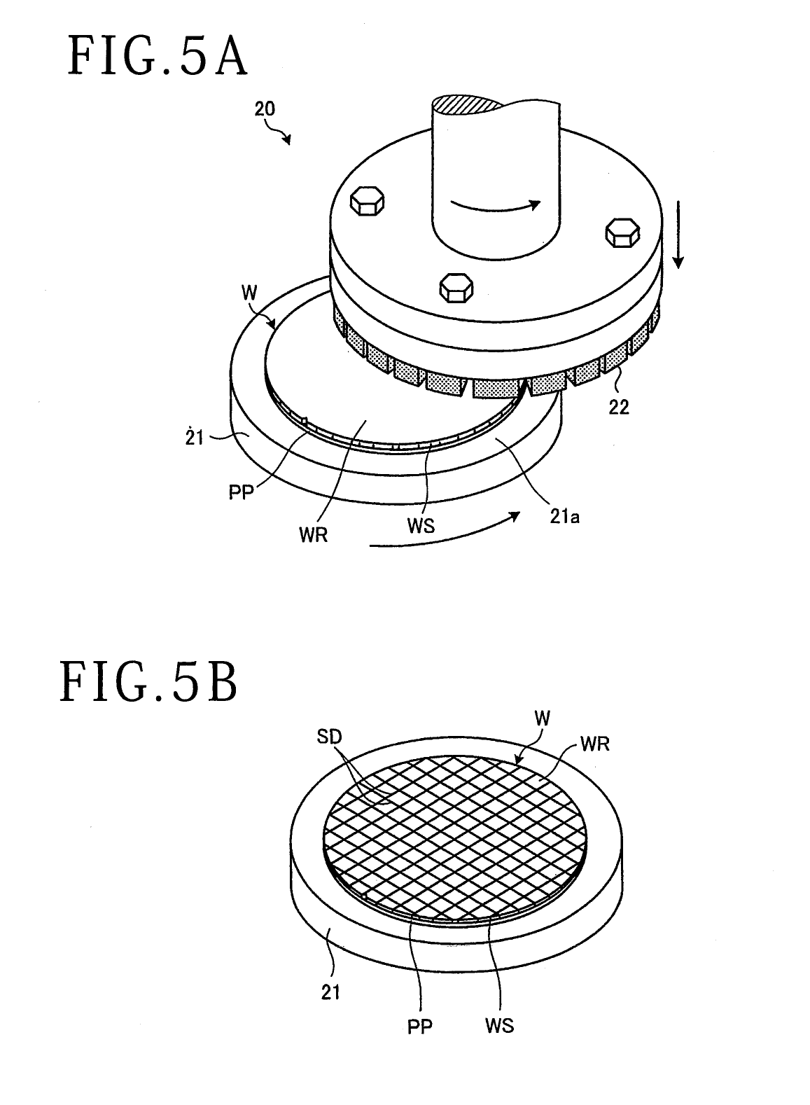

The division step ST30 is a step of dividing the wafer W into individual device chips DT. At the division step ST30, the front face WS of the wafer W is sucked to and held by a holding face 21a of a chuck table 21 of a grinding apparatus 20 through the protective member PP as depicted in FIG. 5A, and then, while grinding whetstones 22 are abutted with the rear face WR of the wafer W, the chuck table 21 and the grinding whetstones 22 are rotated around their axes to perform grinding processing to the rear face WR of the wafer W. At the division step ST30, grinding processing is performed for the wafer W to reduce the thickness of the substrate SB of the wafer W to the finish thickness. At the division step ST30, by reducing the thickness of the substrate SB of the wafer W to the finish thickness, the grooves SD are exposed to the rear face WR side as depicted in FIG. 5B to divide the wafer W into individual device chips DT.

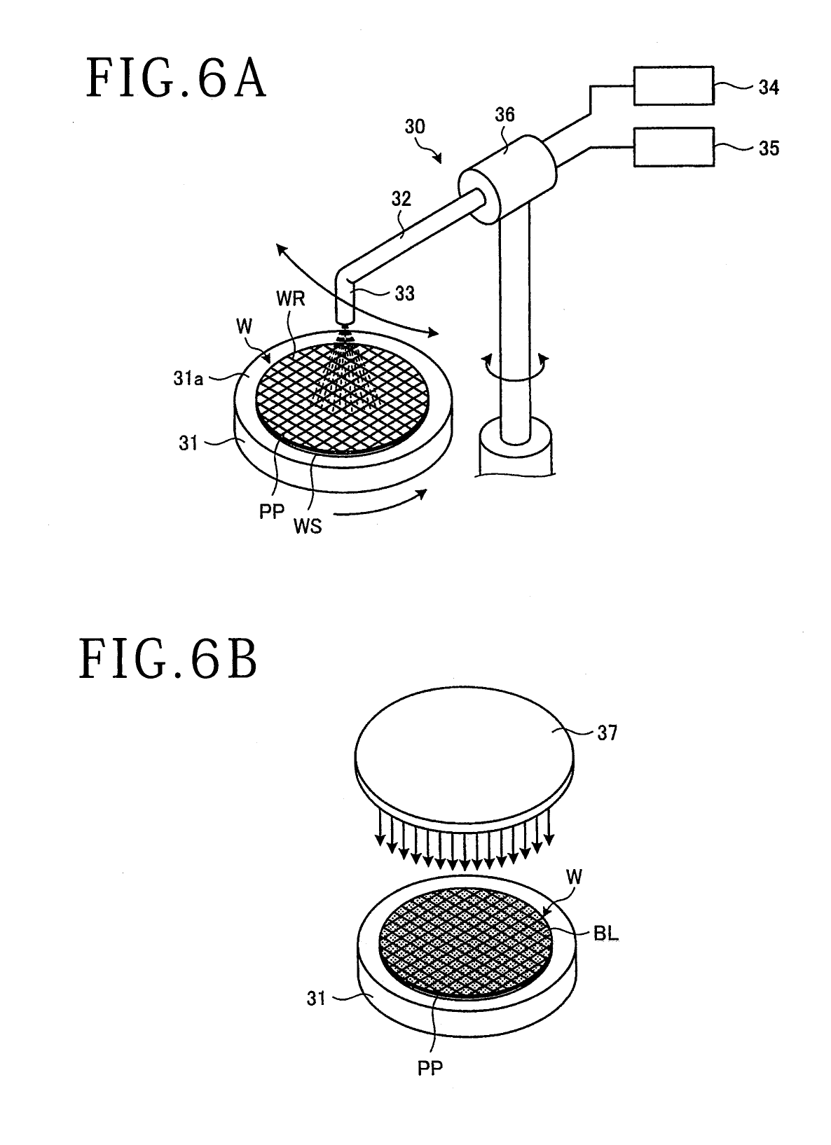

The die bonding resin laying step ST40 is a step of forming an adhesive layer BL on the rear face WR of the substrate SB of the wafer W. At the die bonding resin laying step ST40, the front face WS of the wafer W is sucked to and held by a holding face 31a of a holding table 31 of a die bonding resin laying apparatus 30 through the protective member PP as depicted in FIG. 6A, and mixture of adhesive in the form of liquid and pressurized air is injected from an application nozzle 33 of an application unit 32 to the rear face WR of the substrate SB of the wafer W. The mixture of the adhesive in the form of liquid and the pressurized air is supplied to the application nozzle 33 after the pressurized air from a pressurized air supply source 34 and the adhesive in the form of liquid from a liquid resin tank 35 are mixed by a mixture unit 36. Further, in the first embodiment, at the die bonding resin laying step ST40, while the application nozzle 33 is rocked along an arrow mark in FIG. 6A, the mixture described above is injected to the rear face WR of the substrate SB of the wafer W to apply the adhesive to the rear face WR.

At the die bonding resin laying step ST40, while the application nozzle 33 is rocked by a predetermined number of times, the mixture is injected, and every time the application nozzle 33 is rocked by the predetermined number of times, the rocking of the application nozzle 33 and the injection of the mixture are stopped and ultraviolet rays are irradiated upon the adhesive applied to the rear face WR from a ultraviolet irradiation apparatus 37 as depicted in FIG. 6B to temporarily harden the adhesive. In the first embodiment, at the die bonding resin laying step ST40, application of adhesive in the form of liquid and irradiation of ultraviolet rays are repeated by a plural number of times to form a temporarily hardened adhesive layer BL of a desired thickness. Further, at the die bonding resin laying step ST40, by repeating application of adhesive in the form of liquid and irradiation of ultraviolet rays, the adhesive layer BL can be formed only on the rear face WR of the substrate SB while the adhesive in the form of liquid is prevented from flowing into the grooves SD formed at the separation groove formation step ST10 by the surface tension of the adhesive.

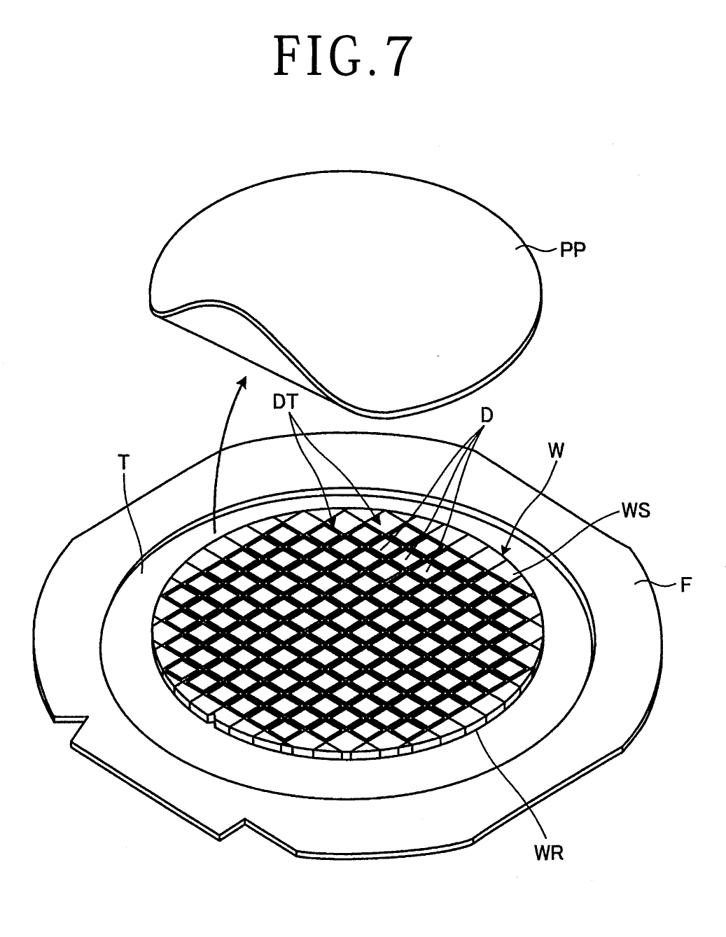

The transfer step ST50 is a step of pasting an adhesive tape T to the rear face WR of the wafer W and exfoliating the protective member PP from the front face WS. At the transfer step ST50, as depicted in FIG. 7, the rear face WR of the wafer W is pasted to the adhesive tape T, which has an annular frame F pasted to an outer periphery thereof, through the adhesive layer BL and then the protective member PP is exfoliated from the front face WS.

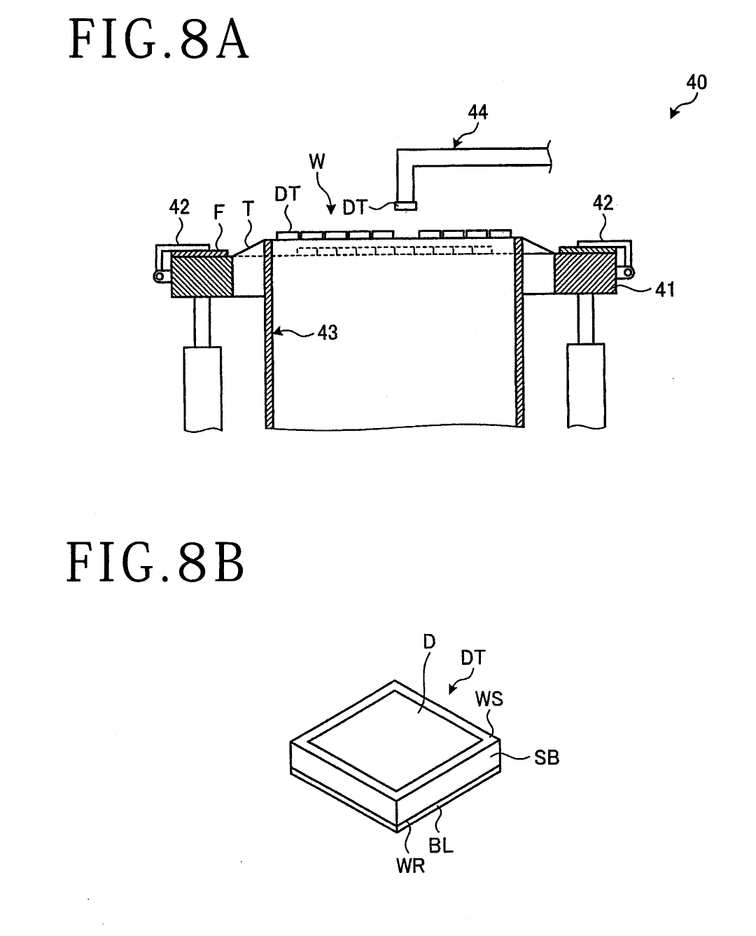

The separation step ST60 is a step of removing the individual device chips DT from the adhesive tape T. At the separation step ST60, the annular frame F is held between a frame holding member 41 and a clamp 42 of a separation apparatus 40. At the separation step ST60, a cylindrical expansion drum 43 of the separation apparatus 40 is pressed against the adhesive tape T between the wafer W and the annular frame F to expand the adhesive tape T as depicted in FIG. 8A thereby to increase the distance between adjacent ones of the device chips DT. At the separation step ST60, the device chips DT are removed one by one from the adhesive tape T using a pickup collet 44 of the separation apparatus 40. In this manner, according to the manufacturing method for the device chip DT, a device chip DT in which a device D is provided on the front face WS of the substrate SB and an adhesive layer BL is provided on the rear face WR as depicted in FIG. 8B is obtained.

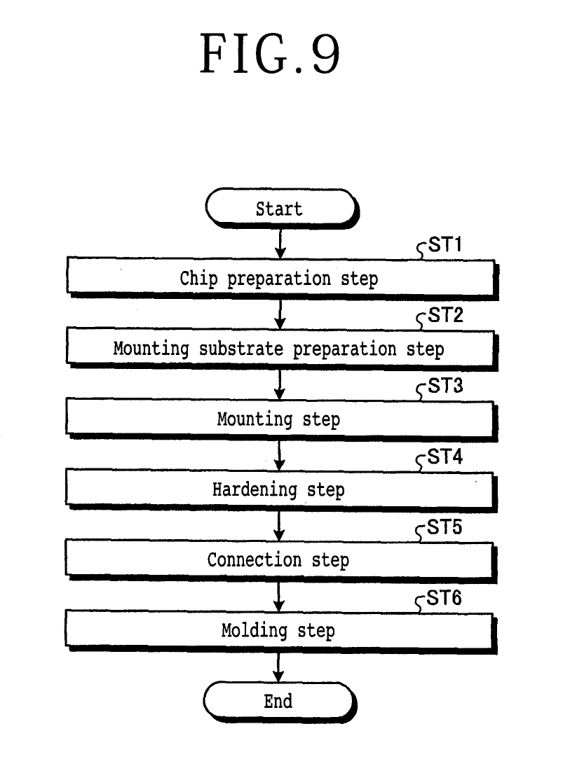

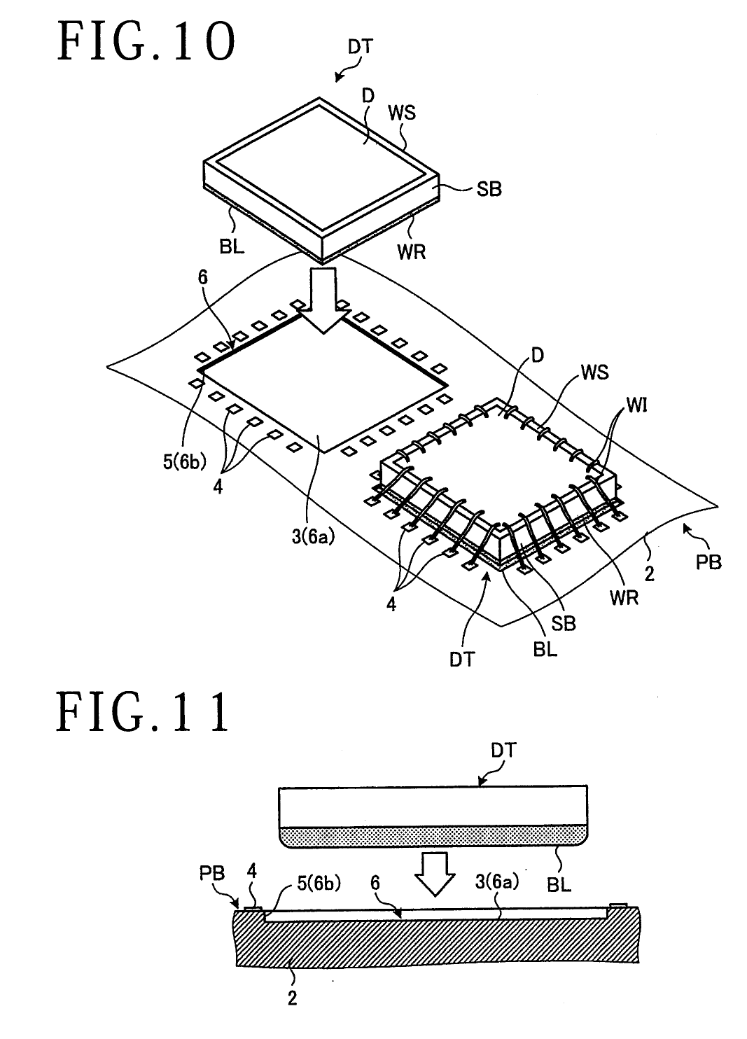

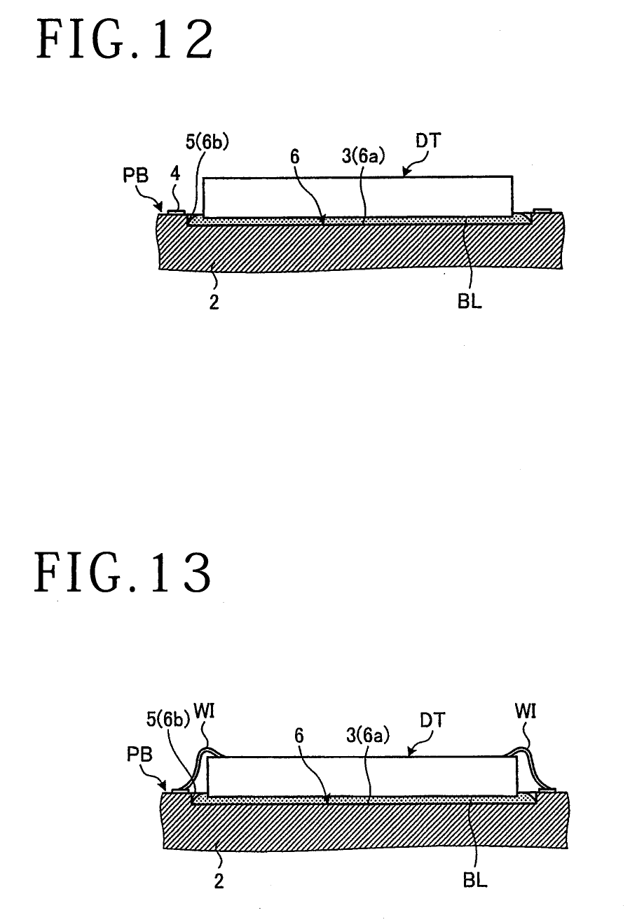

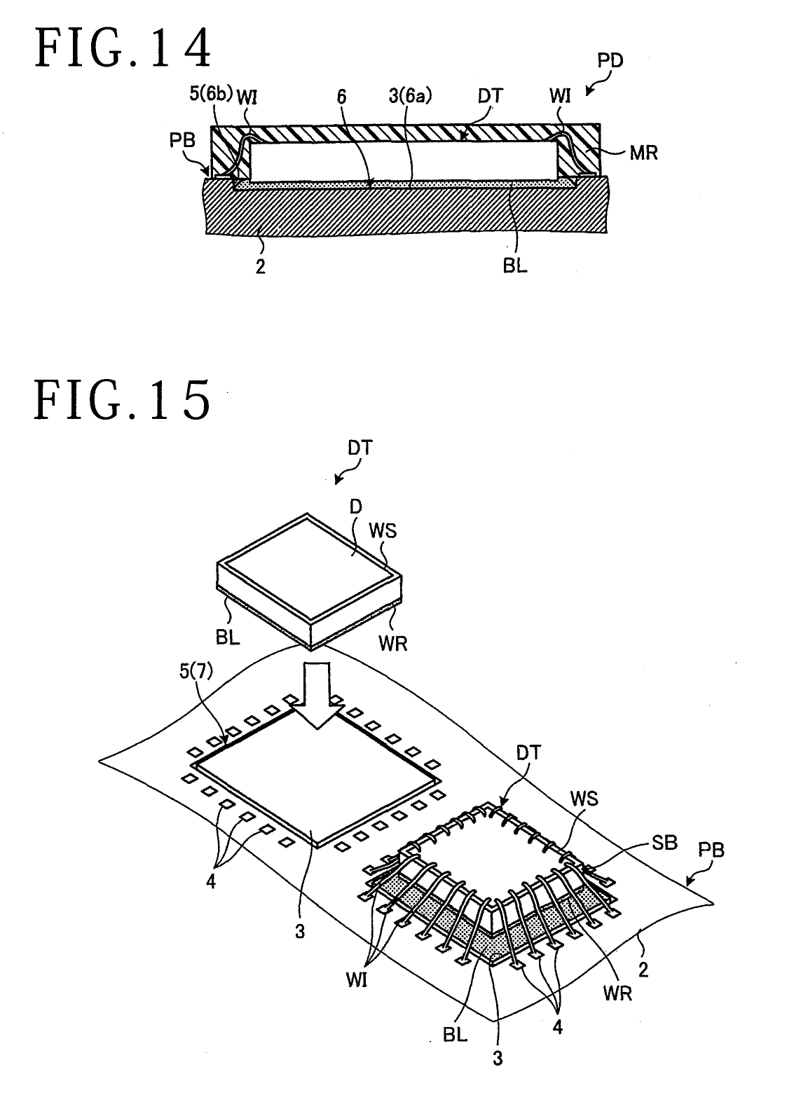

Now, the manufacturing method for the package device PD is described with reference to the drawings. FIG. 9 is a flow chart depicting a flow of the manufacturing method for a package device according to the first embodiment. FIG. 10 is a perspective view depicting the mounting step of the manufacturing method for a package device depicted in FIG. 9. FIG. 11 is a sectional view depicting the mounting step of the manufacturing method for a package device depicted in FIG. 9. FIG. 12 is a sectional view depicting a hardening step of the manufacturing method for a package device depicted in FIG. 9. FIG. 13 is a sectional view depicting a connection step of the manufacturing method for a package device depicted in FIG. 9. FIG. 14 is a sectional view depicting a molding step of the manufacturing method for a package device depicted in FIG. 9.

The manufacturing method for the package device PD is a method for mounting a device chip DT on a mounting substrate PB to manufacture a package device PD. The manufacturing method for the package device PD includes a chip preparation step ST1, a mounting substrate preparation step ST2, a mounting step ST3, a hardening step ST4, a connection step ST5 and a molding step ST6 as depicted in FIG. 9.

The chip preparation step ST1 is a step of preparing a device chip DT manufactured by the manufacturing method for a device chip depicted in FIG. 2. The mounting substrate preparation step ST2 is a step of preparing the mounting substrate PB depicted in FIG. 1. At the mounting substrate preparation step ST2, electrode portions 4 and wiring patterns are formed on the substrate 2 and a recessed portion 6 is formed by cutting, ablation processing by irradiation of a laser beam or the like to prepare a mounting substrate PB on which the stepped portion 5 and the chip adhesion region 3 are formed.

The mounting step ST3 is a step of adhering the device chip DT in the chip adhesion region 3 of the mounting substrate PB through an adhesive layer BL. At the mounting step ST3, the temporarily hardened adhesive layer BL of the device chip DT is opposed to the chip adhesion region 3 first as depicted in FIGS. 10 and 11, and then the adhesive layer BL of the device chip DT is placed on the chip adhesion region 3 and the device chip DT is adhered to the chip adhesion region 3 by the adhesive layer BL.

The hardening step ST4 is a step of applying an external stimulus to harden the adhesive layer BL. In the first embodiment, at the hardening step ST4, heat that is an external stimulus is given to the adhesive layer BL to harden the adhesive layer BL thereby to adhere the device chip DT to the chip adhesion region 3 as depicted in FIG. 12.

The connection step ST5 is a step of electrically connecting the device chip DT and each of the electrode portions 4 of the mounting substrate PB to each other by a wire WI. At the connection step ST5, the wire WI is attached at one end thereof to an electrode of the device chip DT and is attached at the other end thereof to an electrode portion 4 of the mounting substrate PB as depicted in FIG. 13.

The molding step ST6 is a step of covering the device chip DT and the wire WI with mold resin MR. At the molding step ST6, the device chip DT attached to the mounting substrate PB by the adhesive layer BL and connected to the electrode portions 4 of the mounting substrate PB by the wires WI and the wire WI are covered with the mold resin MR as depicted in FIG. 14.

With the manufacturing method for the package device PD according to the first embodiment, since the stepped portion 5 having the face 6b is provided between the chip adhesion region 3 and the electrode portions 4 of the mounting substrate PB, when adhesive in the form of liquid is applied to the chip adhesion region 3, the adhesive can be suppressed from spreading to the outer side of the face 6b of the stepped portion 5 by the surface tension of the adhesive. Consequently, the manufacturing method for the package device PD can suppress the electrode portions 4 from being covered with the adhesive layer BL.

Further, with the manufacturing method for the package device PD according to the first embodiment, since adhesive in the form of liquid is applied to form an adhesive layer BL and application and temporary hardening of the adhesive are repeated by a plural number of times to form the adhesive layer BL, the adhesive that configures the adhesive layer BL can be suppressed from entering the grooves SD between the device chips DT. Therefore, since the manufacturing method for the package device PD according to the first embodiment does not necessitate cutting of the adhesive layer BL between the device chips DT before the separation step ST60 of the manufacturing method for the device chip DT, the time required for manufacturing the device chip DT can be suppressed from becoming long. As a result, the manufacturing method for the package device PD according to the first embodiment can suppress the electrode portions 4 from being covered with the adhesive layer BL while suppressing the time required for manufacturing the package device PD from becoming long.

Further, with the manufacturing method for the package device PD according to the first embodiment, since a difference in height is formed between the chip adhesion region 3 and the electrode portions 4 by the face 6b of the stepped portion 5, the adhesive can be suppressed from spreading to the outer side with respect to the face 6b of the stepped portion 5 by the surface tension of the adhesive.

### Second Embodiment

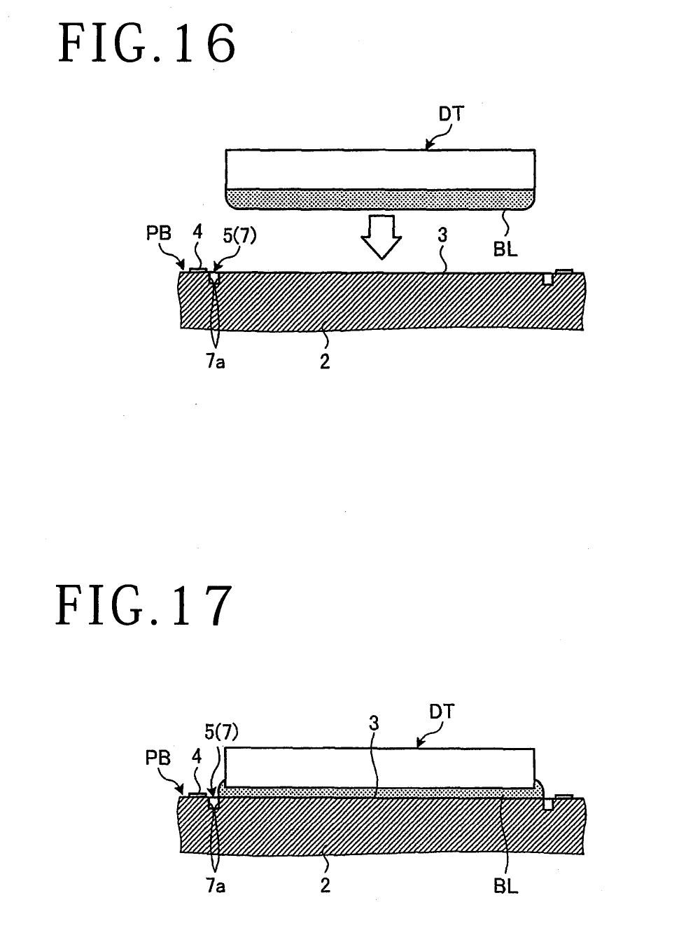

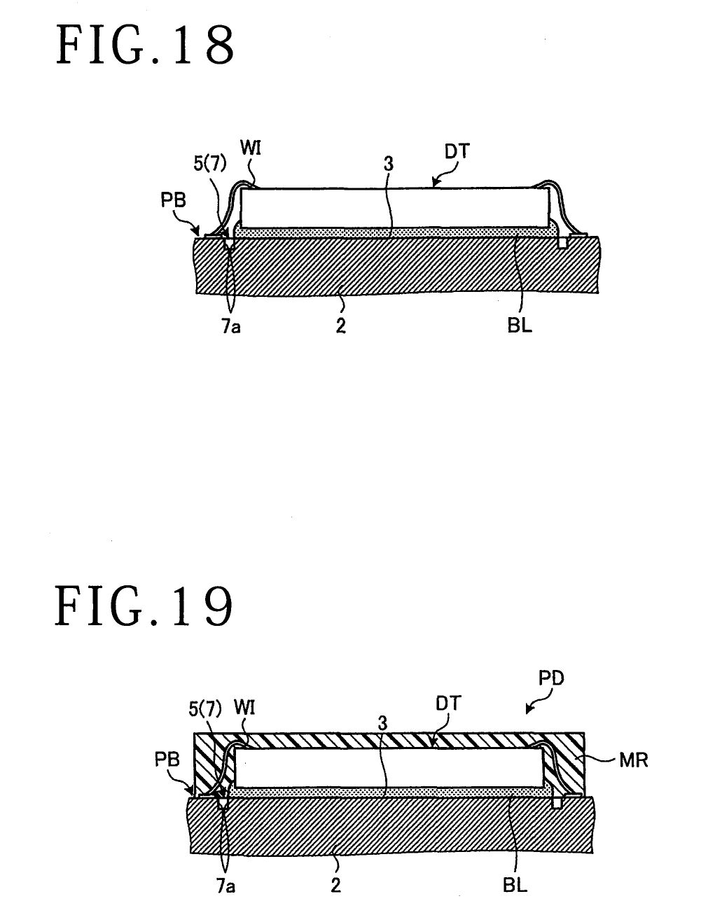

Now, a manufacturing method for a package device PD according to a second embodiment is described with reference to the drawings. FIG. 15 is a perspective view depicting a mounting step of the manufacturing method for a package device according to the second embodiment. FIG. 16 is a sectional view depicting the mounting step of the manufacturing method for a package device according to the second embodiment. FIG. 17 is a sectional view depicting a hardening step of the manufacturing method for a package device according to the second embodiment. FIG. 18 is a sectional view depicting a connection step of the manufacturing method for a package device according to the second embodiment. FIG. 19 is a sectional view depicting a molding step of the manufacturing method for a package device according to the second embodiment. In FIGS. 15 to 19, like elements to those in the first embodiment are denoted by like reference symbols and description of them is omitted.

The manufacturing method for a package device PD according to the second embodiment is same as that according to the first embodiment except that the stepped portion 5 of the mounting substrate PB is a groove 7 and the chip adhesion region 3 is formed from the front face of the substrate 2. The groove 7 is formed recessed from the front face of the substrate 2 and surrounds the outer side of the device chip DT over an overall periphery of the device chip DT. Further, in the second embodiment, the groove 7 that is the stepped portion 5 has an inner side face 7a orthogonal to the front face of the substrate 2 that is the chip adhesion region 3. An angular portion existing at a connection portion between the inner side face 7a of the groove 7 and the mounting substrate PB acts to suppress the adhesive, which configures the adhesive layer BL, from leaking to the outside of the chip adhesion region 3 utilizing the surface tension of the adhesive that configures the adhesive layer BL. Further, even if the adhesive protrudes from the angular portion since the groove 7 has a volume into which the adhesive is accommodated, the adhesive is suppressed from protruding until it covers the electrode portions 4.

In the manufacturing method for the package device PD according to the second embodiment, similarly as in the first embodiment, a device chip DT is prepared at the chip preparation step ST1, and then at the mounting substrate preparation step ST2, a mounting substrate PB is prepared. Then at the mounting step ST3, as depicted in FIGS. 15 and 16, the temporarily hardened adhesive layer BL of the device chip DT is opposed to the chip adhesion region 3, whereafter the adhesive layer BL of the device chip DT is placed on the chip adhesion region 3 and the device chip DT is adhered to the chip adhesion region 3 by the adhesive layer BL.

Further, in the manufacturing method for the package device PD according to the second embodiment, at the hardening step ST4, the adhesive layer BL is heated or the like together with the mounting substrate PB to adhere the device chip DT to the chip adhesion region 3 as depicted in FIG. 17, and at the connection step ST5, the device chip DT and each of the electrode portions 4 of the mounting substrate PB are electrically connected to each other by a wire WI as depicted in FIG. 18. Further, at the molding step ST6, the device chip DT and the wire WI are covered with mold resin MR as depicted in FIG. 19.

Since the manufacturing method for the package device PD according to the second embodiment provides a stepped portion 5 having an inner side face 7a between a chip adhesion region 3 and electrode portions 4 of a mounting substrate PB and repeats application and temporary hardening of adhesive by a plural number of times to form an adhesive layer BL, the electrode portions 4 can be suppressed from being covered with the adhesive layer BL while it is suppressed that the time required for manufacturing the package device PD becomes long.

Further, in the manufacturing method for the package device PD according to the second embodiment, since the stepped portion 5 is a groove SD having the inner side face 7a, the adhesive can be suppressed from spreading to the outer side with respect to the inner side face 7a of the stepped portion 5 by the surface tension of the adhesive.

### Third Embodiment

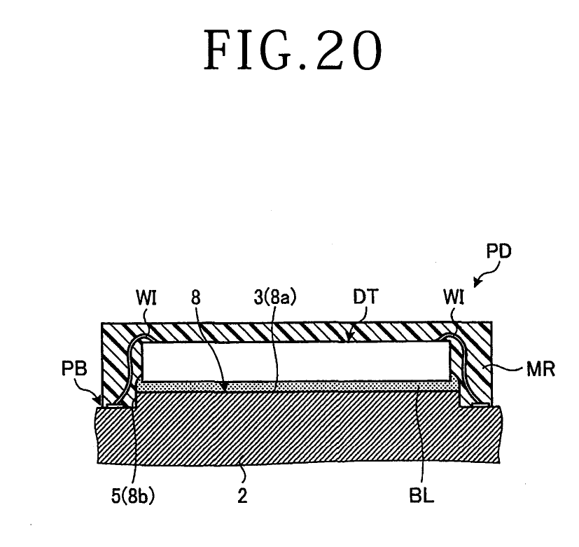

Now, a manufacturing method for a package device PD according to a third embodiment is described with reference to the drawing. FIG. 20 is a sectional view depicting a package device manufactured by a manufacturing method for a package device according to a third embodiment. In FIG. 20, like elements to those in the first embodiment are denoted by like reference symbols and description of them is omitted.

The third embodiment is similar to the first embodiment except that the chip adhesion region 3 of the package device PD is an upper face 8a of a projected portion 8 formed so as to be projected from the front face of the substrate 2 and the stepped portion 5 has an outer side face 8b orthogonal to the upper face 8a that is the chip adhesion region 3 as depicted in FIG. 20. An angular portion that is a connection portion between the outer side face 8b and the chip adhesion region 3 acts to suppress adhesive, which configures an adhesive layer BL, from leaking to the outer side of the chip adhesion region 3 utilizing the surface tension of the adhesive that configures the adhesive layer BL. Further, in the third embodiment, since the chip adhesion region 3 is the upper face 8a of the projected portion 8, a difference in height in the thicknesswise direction of the substrate 2 is formed between the chip adhesion region 3 and the electrode portions 4 by the outer side face 8b of the stepped portion 5.

In the manufacturing method for the package device PD according to the third embodiment, since the stepped portion 5 having the outer side face 8b is provided between the chip adhesion region 3 and the electrode portions 4 of the mounting substrate PB and application and temporary hardening of the adhesive are repeated by a plural number of times to form the adhesive layer BL, the electrode portions 4 can be suppressed from being covered with the adhesive layer BL while it is suppressed that the time required for manufacturing the package device PD becomes long.

Further, in the manufacturing method for the package device PD according to the third embodiment, since a difference in height is formed between the chip adhesion region 3 and the electrode portions 4 by the outer side face 8b of the stepped portion 5, the adhesive can be suppressed from spreading to the outer side with respect to the outer side face 8b of the stepped portion 5 by the surface tension of the adhesive.

It is to be noted that the present invention is not limited to the embodiments described above. In particular, the present invention can be carried out in various modified forms without departing from the spirit and scope of the present invention.

The present invention is not limited to the details of the above described preferred embodiments. The scope of the invention is defined by the appended claims and all changes and modifications as fall within the equivalence of the scope of the claims are therefore to be embraced by the invention.

What is claimed is:

1. A manufacturing method for a package device, comprising:
a chip preparation step of preparing a device chip that includes an adhesive layer applied in the form of liquid and temporarily hardened on one face thereof;
a mounting substrate preparation step of preparing a mounting substrate that has, on a front face thereof, a chip adhesion region to which the device chip is to be adhered, an electrode portion that is provided in the proximity of the chip adhesion region and is to be electrically connected to the adhered device chip, and a stepped portion formed between the chip adhesion region and the electrode portion;
a mounting step of adhering the device chip to the chip adhesion region of the mounting substrate through the adhesive layer;
a hardening step of giving, after the mounting step is carried out, an external stimulus to the adhesive layer to harden the adhesive layer;
a connection step of electrically connecting, after the hardening step is carried out, the device chip and the electrode portion by a wire; and
a molding step of covering, after the connection step is carried out, the device chip and the wire with mold resin;
the stepped portion suppressing the adhesive layer in the temporarily hardened state from protruding to the electrode portion.

2. The manufacturing method for a package device according to claim 1, wherein a difference in height is formed between the chip adhesion region and the electrode portion by the stepped portion.

3. The manufacturing method for a package device according to claim 1, wherein the stepped portion is a groove formed between the chip adhesion region and the electrode portion.
